(19) United States
(12) Patent Application Publication
(10) Pub. No.: US 2025/0385156 A1
(43) Pub. Date: Dec. 18, 2025

(54) HEAT DISSIPATION FILM, DISPLAY MODULE, AND DISPLAY APPARATUS

(71) Applicants: CHONGQING BOE DISPLAY TECHNOLOGY CO., LTD., Beibei District, Chongqing (CN); BOE TECHNOLOGY GROUP CO., LTD., Beijing (CN)

(72) Inventors: Wei Chen, Beijing (CN); Xiaoxia Huang, Beijing (CN); Mengliang Yao, Beijing (CN); Hufei Yang, Beijing (CN); Ajuan Du, Beijing (CN); Yunhui Huang, Beijing (CN); Yiqian Wu, Beijing (CN); Guodong Zeng, Beijing (CN); Hao Sun, Beijing (CN); Enjian Yang, Beijing (CN); Yilun Zeng, Beijing (CN); Yongle Wang, Beijing (CN)

(73) Assignees: CHONGQING BOE DISPLAY TECHNOLOGY CO., LTD., Beibei District, Chongqing (CN); BOE TECHNOLOGY GROUP CO., LTD., Beijing (CN)

(21) Appl. No.: 18/881,048

(22) PCT Filed: May 22, 2024
(86) PCT No.: PCT/CN2024/094793

§ 371 Date: Jan. 3, 2025

(30) Foreign Application Priority Data
May 31, 2023 (CN) 202310640181.3

(51) Int. Cl. H01L 23/373

(52) U.S. Cl. CPC H01L 23/3735

(57) ABSTRACT

A heat dissipation film, a display module and a display apparatus are provided, wherein the heat dissipation film includes a main body region and an edge region located at one side of the main body region, the heat dissipation film includes a composite film layer; the composite film layer in the main body region includes an adhesive layer, a buffer layer and a first metal portion of a metal layer that are arranged in layer configuration, and the composite film layer in the edge region includes a second metal portion of the metal layer; a thickness of the composite film layer in the edge region is less than a thickness of the composite film layer in the main body region.

### CROSS-REFERENCE TO RELATED APPLICATION

This application claims the priority of the Chinese Patent application filed on May 31, 2023 before the China National Intellectual Property Administration with the application number of 202310640181.3, and the title of “HEAT DISSIPATION FILM, DISPLAY MODULE, AND DISPLAY APPARATUS”, which is incorporated herein in its entirety by reference.

### FIELD

The present disclosure relates to the technical field of displaying and, more particularly, to a heat dissipation film, a display module and a display apparatus.

### BACKGROUND

With the acceleration of electronic device upgrading and updating, the requirements for the integration and performance of the display panel are becoming increasingly high, so that the display panel generate more and more heat in the working process. Currently, the display panel is mainly cooled by attaching a heat dissipation film to the display panel.

### SUMMARY

A heat dissipation film is provided by the present disclosure, which includes a main body region and an edge region located at one side of the main body region, the heat dissipation film including a composite film layer; the composite film layer in the main body region including an adhesive layer, a buffer layer and a first metal portion of a metal layer that are arranged in layer configuration, and the composite film layer in the edge region including a second metal portion of the metal layer, wherein a thickness of the composite film layer in the edge region is less than a thickness of the composite film layer in the main body region;
the adhesive layer and the buffer layer do not overlap with the edge region in a normal direction of the heat dissipation film;
the metal layer further includes
a connecting portion configured to connect the first metal portion and the second metal portion;
wherein the first metal portion, the second metal portion and the connecting portion jointly cover the main body region and the edge region in the normal direction of the heat dissipation film.

In some embodiments, the metal layer includes a first surface; a first surface of the first metal portion is in contact with the buffer layer, and a first surface of the second metal portion is located in a same plane as a surface of a side of the adhesive layer facing away from the first metal portion.

In some embodiments, the metal layer further includes a second surface disposed opposite to the first surface; the heat dissipation film further includes:
a support structure located in the edge region and disposed on a second surface of the second metal portion; and
a surface of a side of the support structure facing away from the second metal portion is located in a same plane as a second surface of the first metal portion.

In some embodiments, the heat dissipation film further includes:
a first release protective film located in the edge region and disposed at the side of the support structure facing away from the second metal portion;
wherein the support structure includes a support pad, a single surface of the support pad is provided with an adhesive, and the adhesive-provided surface faces the first release protective film.

In some embodiments, the heat dissipation film further includes:
a second release protective film located in the main body region and disposed on the second surface of the first metal portion.

In some embodiments, wherein the support structure includes:
a first double-sided adhesive pad adhered to and fixed on the second surface of the second metal portion; and
a removable pad disposed at a side of the first double-sided adhesive pad facing away from the second metal portion, wherein the removable pad is removable from the side of the first double-sided adhesive pad facing away from the second metal portion.

In some embodiments, the heat dissipation film further includes:
a bottom protective film disposed at a side of the adhesive layer facing away from the metal layer;
wherein the bottom protective film is capable of being torn off in a process of attaching

the heat dissipation film to a display panel.

In some embodiments, the adhesive layer is a grid-like adhesive layer to remove air bubbles in a process of attaching the heat dissipation film.

In some embodiments, the metal layer is a copper foil layer.

A display module is provided by the present disclosure, which includes:
a display panel, including a display region, a bending region and a binding region, wherein the binding region is bent to a side of the display region facing away from a light-emitting side through the bending region; and
the heat dissipation film according to some embodiments stated above, wherein the heat dissipation film is located between the display region and the binding region, the adhesive layer is disposed close to the display region, and an orthographic projection of the binding region on the heat dissipation film overlaps with the edge region.

In some embodiments, the display module further includes:
a second double-sided adhesive pad disposed between a composite film layer in the edge region and the binding region and configured to adhere and fix the binding region at a side of the composite film layer in the edge region facing away from the display region.

In some embodiments, in a state where a compression ratio is 25%, a compression force deflection value of the second double-sided adhesive pad and a compression force deflection value of the buffer layer are greater than or equal to 0.02 MPa and less than or equal to 0.4 MPa.

In some embodiments, a substrate of the second double-sided adhesive pad is the same as a material of the buffer layer.

In some embodiments, a substrate of the second double-sided adhesive pad and a material of the buffer layer include foam.

In some embodiments, a thickness of the second double-sided adhesive pad is greater than or equal to 0.03 mm.

In some embodiments, the display module further includes:
a first support film disposed between the display region and the heat dissipation film, wherein an end surface of the first support film facing the bending region includes a first side edge close to the display region and a second side edge away from the display region; an orthographic projection of the first side edge on a plane where the display region is located is located at a side of an orthographic projection of the second side edge on the plane where the display region is located away from the bending region.

In some embodiments, a distance between the orthographic projection of the first side edge on the plane where the display region is located and the orthographic projection of the second side edge on the plane where the display region is located is greater than or equal to 0.02 mm and less than or equal to 0.05 mm.

In some embodiments, the first support film includes a base film, and a bottom film and a release film located at two sides of the base film;
a side of the base film close to the bottom film is provided with an adhesive for adhering and fixing the base film to the display region after the bottom film is torn off; and
the release film is capable of being torn off when the base film is attached to the heat dissipation film.

In some embodiments, a shape of a longitudinal cross-section of the bending region is semi-circular or semi-elliptical, and the longitudinal cross-section is perpendicular to the plane where the display region is located and perpendicular to a boundary line between the display region and the bending region.

A display apparatus is provided by the present disclosure, which includes:
the display module according to any one of embodiments stated above; and
a drive assembly connected to a binding region of the display panel and configured to drive the display panel to display a picture.

The above description is only a summary of technical schemes of the present disclosure, which can be implemented according to contents of the specification in order to better understand technical means of the present disclosure; and in order to make above and other objects, features and advantages of the present disclosure more obvious and understandable, detailed description of the present disclosure is particularly provided in the following.

### BRIEF DESCRIPTION OF THE DRAWINGS

In order to more clearly illustrate the technical solutions of the embodiments of the present disclosure or the related art, the figures that are required to describe the embodiments or the related art may be briefly introduced below. Apparently, the figures that are described below are embodiments of the present disclosure, and a person skilled in the art can obtain other figures according to these figures without paying creative work. It should be noted that the proportions in the drawings are only indicative and do not represent actual proportions.

FIG. 1 exemplarily shows a schematic cross-sectional structure of a display module in the related art;

FIG. 2 exemplarily shows a schematic cross-sectional structure of a first heat dissipation film according to the present disclosure;

FIG. 3 exemplarily shows a schematic cross-sectional structure of a second heat dissipation film according to the present disclosure;

FIG. 4 exemplarily shows a schematic cross-sectional structure of a heat dissipation film prepared by using a roller;

FIG. 5 exemplarily shows a schematic cross-sectional structure of a double-sided adhesive pad according to the present disclosure;

FIG. 6 exemplarily shows a schematic cross-sectional structure of a first display module according to the present disclosure;

FIG. 7 exemplarily shows a schematic cross-sectional structure of a second display module according to the present disclosure; and

FIG. 8 exemplarily shows a schematic cross-sectional structure of a first support film according to the present disclosure.

### DETAILED DESCRIPTION

In order to make the objects, the technical solutions and the advantages of the embodiments of the present disclosure clearer, the technical solutions of the embodiments of the present disclosure may be clearly and completely described below with reference to the drawings of the embodiments of the present disclosure. Apparently, the described embodiments are merely certain embodiments of the present disclosure, rather than all of the embodiments. All of the other embodiments that a person skilled in the art obtains on the basis of the embodiments of the present disclosure without paying creative work fall within the protection scope of the present disclosure.

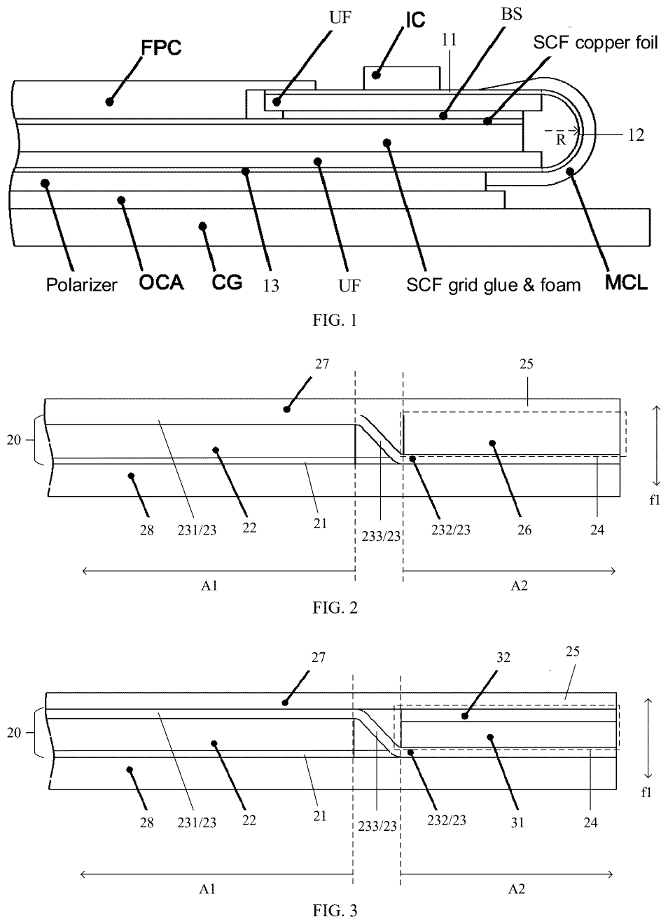

In the related art, a binding region 11 pad bending technique is generally adopted by a flexible display panel to achieve the effect of a narrow frame. As shown in FIG. 1, which shows a cross-sectional structure of a display panel at a frame in the related art. As shown in FIG. 1, a binding region 11 of the display panel is bent to a back surface of a display region 13 through a bending region 12. A bending radius R of the bending region 12 is a key factor affecting the size of the frame.

In FIG. 1, film layers located between the display region 13 and the binding region 11 include a back film UF, a heat dissipation film SCF (including the SCF grid glue & foam and SCF copper foil shown in FIG. 1), and a double-sided adhesive pad BS. The bending radius R is 0.2 mm, and a thickness of the back film UF is 0.088 mm. A total thickness of the heat dissipation film SCF and the double-sided adhesive pad BS=the bending radius R×2−the thickness of the back film UF×2=0.2 mm×2−0.088 mm×2=0.224 mm. The thinning of the thickness of the back film UF means a large increase in cost, and the thinning amplitude of the back film UF is very limited. Thus, if the bending radius R needs to be further reduced, the thickness of the heat dissipation film SCF or the thickness of the double-sided adhesive pad BS may be thinned. However, further thinning of the double-sided adhesive pad BS may result in insufficient adhesion of the double-sided adhesive, and further thinning of the heat dissipation film SCF may result in mold printing on a display surface of the display panel.

In order to meet the requirement of further narrowing the frame, as shown in FIG. 2 or FIG. 3, the heat dissipation film 62 includes a main body region A1 and an edge region A2 located at one side of the main body region A1. The heat dissipation film 62 includes a composite film layer 20. The composite film layer 20 in the main body region A1 includes an adhesive layer 21, a buffer layer 22 and a first metal portion 231 of a metal layer 23 that are arranged in layer configuration, and the composite film layer in the edge region A2 includes a second metal portion 232 of the metal layer 23. The composite film layer 20 in the edge region A2 has a different structure from the composite film layer 20 in the main body region A1, and a thickness of the composite film layer 20 in the edge region A2 is less than a thickness of the composite film layer 20 in the main body region A1.

As shown in FIG. 2 or FIG. 3, the adhesive layer 21 and the buffer layer 22 do not overlap with the edge region A2 in a normal direction f1 of the heat dissipation film 62. That is, the edge region A2 does not include the adhesive layer 21 and the buffer layer 22, and the adhesive layer 21 and the buffer layer 22 are located only in the main body region A1.

As shown in FIG. 2 or FIG. 3, the metal layer 23 includes: a first metal portion 231 located in the main body region A1; a second metal portion 232 located in the edge region A2; and a connecting portion 233 configured to connect the first metal portion 231 and the second metal portion 232. The first metal portion 231, the second metal portion 232 and the connecting portion 233 jointly cover the main body region A1 and the edge region A2 in the normal direction f1 of the heat dissipation film 62.

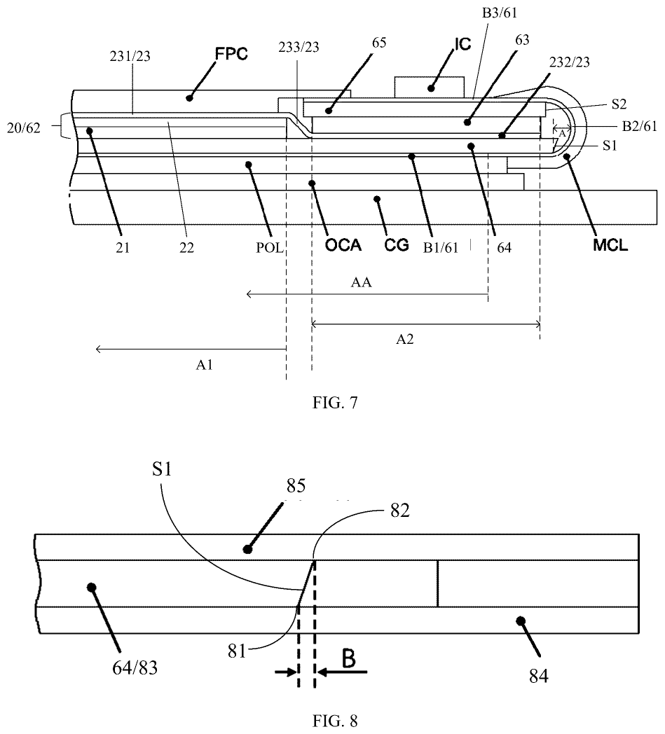

By disposing the composite film layer 20 with a small thickness in the edge region A2 may reduce the thickness of the heat dissipation film 62 in the edge region A2. The heat dissipation film 62 provided by the present disclosure may be applied to a display module. As shown in FIG. 6 or FIG. 7, a binding region B3 of the display panel 61 is disposed in the edge region A2 of the heat dissipation film 62, and the thinned edge region A2 facilitates reducing the bending radius of the bending region B2, thereby facilitating reducing the size of the frame.

Further, the adhesive layer 21 and the buffer layer 22 in the edge region A2 are removed, and the adhesive layer 21 and the buffer layer 22 are disposed only in the main body region A1 to realize that the thickness of the composite film layer 20 in the edge region A2 is thinned.

As shown in FIG. 2 or FIG. 3, the composite film layer 20 in the main body region A1 includes the adhesive layer 21, the buffer layer 22 and the first metal portion 231 that are arranged in layer configuration, and the composite film layer 20 in the edge region A2 includes the second metal portion 232. The first metal portion 231, the second metal portion 232 and the connecting portion 233 are intercommunicated as an integrated structure, such as being different parts of the same metal sheet.

Disposing the metal layer 23 in both the edge region A2 and the main body region A1 facilitates the heat in the binding region B3 spreading evenly through the metal layer 23, thereby affecting the display and service life of the display panel 61 due to local heat concentration is avoided.

Based on the experience, in performing flat panel electrostatic field verification, of the inventor, regions without metal shielding may experience severe greening or abnormal display problems when flat panel electrostatic field testing is performed. In the present embodiment, providing the metal layer 23 in both the edge region A2 and the main body region A1 may avoid the problem of greening or abnormal display of a display picture. In addition, by disposing that the second metal portion 232 is disposed in the edge region A2 to shield the binding region B3 from the display region B1, mutual interference between a drive signal of the binding region B3 and a display signal of the display region B1 is avoided, and normal display is ensured.

In some embodiments, the metal layer 23 includes a first surface and a second surface disposed oppositely. It may be appreciated that, since the metal layer 23 includes the first metal portion 231 and the second metal portion 232, and the first metal portion 231, the second metal portion 232 and the connecting portion 233 are intercommunicated as an integrated structure, a first surface of the first metal portion 231 and a first surface of the second metal portion 232 are different parts in the first surface of the metal layer 23, and a second surface of the first metal portion 231 and a second surface of the second metal portion 232 are also different parts in the second surface of the metal layer 23. The first surface of the first metal portion 231 is in contact with the buffer layer 22. Therefore, as shown in FIG. 2 or FIG. 3, the first surface is a lower surface of the metal layer 23 shown in FIGS. 2 and 3, and the second surface is an upper surface of the metal layer 23 shown in FIGS. 2 and 3.

In some embodiments, as shown in FIG. 2 or FIG. 3, the first surface of the second metal portion 232 (the lower surface of the second metal portion 232 shown in FIGS. 2 and 3) is located in a same plane as a surface of a side of the adhesive layer 21 facing away from the first metal portion 231 (a lower surface of the adhesive layer 21 shown in FIGS. 2 and 3).

Exemplarily, the heat dissipation film 62 may be made in a roll-to-roll manner, and a surface of a side of the metal layer 23 facing away from the adhesive layer 21 is rolled through a roller 41 to achieve the attachment of the metal layer 23. In order to press the lower surface of the second metal portion 232 and the lower surface of the adhesive layer 21 to the same plane, as shown in FIG. 4, a part of the roller 41 corresponding to the second metal portion 232 may be locally thickened, and a rolling direction of the roller 41 may be along a boundary line between the main body region A1 and the edge region A2. In this way, the structure of the metal layer 23 shown in FIG. 2 or FIG. 3 may be made so that the thickness of the composite film layer in the edge region A2 is less than the thickness of the composite film layer in the main body region A1.

In some embodiments, as shown in FIG. 2 or FIG. 3, the heat dissipation film 62 further includes: a support structure 24 located in the edge region A2 and disposed on the second surface of the second metal portion 232. A surface of a side of the support structure 24 facing away from the second metal portion 232 (an upper surface of the support structure 24 shown in FIGS. 2 and 3) is located in a same plane as the second surface of the first metal portion 231 (the upper surface of the first metal portion 231 shown in FIGS. 2 and 3).

Since the thickness of the composite film layer 20 in the edge region A2 is less than the thickness of the composite film layer 20 in the main body region A1, by disposing the support structure 24 at the side of the second metal portion 232 in the edge region A2 facing away from the adhesive layer 21, the difference in thicknesses between the main body region A1 and the edge region A2 may be compensated for, so that the thickness of the heat dissipation film 62 is kept consistent in different regions, thereby the mold printing problem caused by the uneven thickness of the heat dissipation film 62 when the heat dissipation film 62 is attached can be avoided.

In some embodiments, as shown in FIG. 2, the heat dissipation film 62 further includes: a first release protective film 25 located in the edge region A2 and disposed at the side of the support structure 24 facing away from the second metal portion 232. The support structure 24 includes: a support pad 26. A single surface of the support pad 26 is provided with an adhesive, and the adhesive-provided surface faces the first release protective film 25.

The first release protective film 25 may be torn off in the process of bending and fixing the binding region B3 after the heat dissipation film 62 is attached to the display panel 61. Since the adhesive-provided surface of the support pad 26 faces the first release protective film 25, and a non-adhesive-provided surface of the support pad 26 faces the second metal portion 232, i.e., the support pad 26 is adhered to the first release protective film 25, the support pad 26 is also torn off while the first release protective film 25 is torn off.

Exemplarily, as shown in FIG. 2, the heat dissipation film 62 may further include: a second release protective film 27 located in the main body region A1 and disposed at a side of the first metal portion 231 facing away from the adhesive layer 21. The second release protective film 27 may be torn off when the entire machine is assembled (such as when a printed circuit board FPC is attached).

In some embodiments, as shown in FIG. 3, the support structure 24 includes: a first double-sided adhesive pad 31 adhered to and fixed at the side of the second metal portion 232 facing away from the adhesive layer 21, and a removable pad 32 disposed at a side of the first double-sided adhesive pad 31 facing away from the second metal portion 232. The removable pad 32 can be removable from the side of the first double-sided adhesive pad 31 facing away from the second metal portion 232.

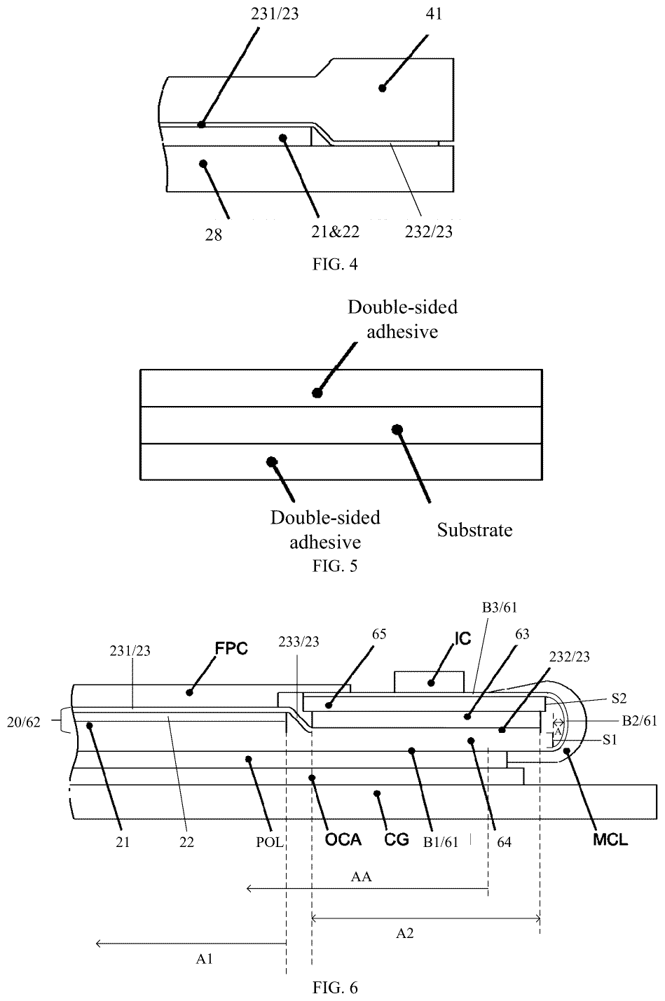

Exemplarily, the removable pad 32 may be torn off in the process of bending and fixing the binding region B3 after the heat dissipation film 62 is attached to the display panel 61. For example, the first double-sided adhesive pad 31 may have an adhesive-substrate-adhesive double-sided adhesive structure. As shown in FIG. 5, the first double-sided adhesive pad 31 is configured to adhere and fix the binding region B3 of the display panel 61 at a side of the second metal portion 232 facing away from the display region B1.

By integrating the first double-sided adhesive pad 31 in the heat dissipation film 62, the assembly of the composite film layer 20 and the first double-sided adhesive pad 31 may be completed by using a one-step attaching process, thereby the process steps are simplified.

Exemplarily, as shown in FIG. 2 or FIG. 3, the heat dissipation film 62 may further include a bottom protective film 28 disposed at a side of the adhesive layer 21 facing away from the metal layer 23. The bottom protective film 28 may be torn off in the process of attaching the heat dissipation film 62 to the display panel 61.

Exemplarily, the adhesive layer 21 may be a grid-like adhesive layer that facilitates the removal of air bubbles in the process of attaching the heat dissipation film 62.

Exemplarily, the main material of the buffer layer 22 may include foam, and the buffer layer 22 plays a role in buffering to prevent the display panel 61 from generating mold printing during the assembly process. In order to ensure that the buffer layer 22 plays a role in effective buffering, the thickness of the buffer layer 22 may be, for example, greater than or equal to 0.19 mm.

Exemplarily, the metal layer 23 may be a copper foil layer, which is configured to cool the display panel 61 and may also play a role in electromagnetic shielding.

A display module is provided by the present disclosure. As shown in FIG. 6 or FIG. 7, the display module includes: a display panel 61 including a display region B1, a bending region B2 and a binding region B3, wherein the binding region B3 is bent to a side of the display region B1 facing away from a light-emitting side through the bending region B2; and the heat dissipation film 62 as provided in some embodiments stated above, the heat dissipation film 62 is located between the display region B1 and the binding region B3, the adhesive layer 21 is disposed close to the display region B1, and an orthographic projection of the binding region B3 on the heat dissipation film 62 overlaps with the edge region A2.

It can be appreciated by a person skilled in the art that the display module provided by the present disclosure has the advantages of the above-mentioned heat dissipation film 62.

Exemplarily, as shown in FIG. 6 or FIG. 7, the main body region A1 of the heat dissipation film 62 is adhered to the side of the display region B1 facing away from the light-emitting side through the adhesive layer 21. A single surface of the metal layer 23 is provided with an adhesive, and the adhesive-provided surface faces the display region B1. The edge region A2 of the heat dissipation film 62 is adhered to the side of the display region B1 facing away from the light-emitting side through an adhesive-provided surface of the second metal portion 232.

In some embodiments, as shown in FIG. 6 or FIG. 7, the display module further includes: a second double-sided adhesive pad 63 disposed between the composite film layer 20 in the edge region A2 and the binding region B3 and configured to adhere and fix the binding region B3 at a side of the composite film layer 20 facing away from the display region B1.

As shown in FIG. 5, for example, the second double-sided adhesive pad 63 may have an adhesive-substrate-adhesive double-sided adhesive structure.

The second double-sided adhesive pad 63 may be the first double-sided adhesive pad 31 integrated in the heat dissipation film 62, or may be a double-sided adhesive pad separate from the heat dissipation film 62, which is not limited in the present disclosure.

In some embodiments, in a state where a compression ratio is 25%, a compression force deflection (CFD) value of the second double-sided adhesive pad 63 and a CFD value of the buffer layer 22 are greater than or equal to 0.02 MPa and less than or equal to 0.4 MPa.

By setting the CFD value of the second double-sided adhesive pad 63 and the CFD value of the buffer layer 22 at the same compression ratio to be in the same interval range, the difference in attachment pressure experienced by the display panel 61 in the main body region A1 and the edge region A2 in the process of attaching the heat dissipation film 62 may be reduced, thereby facilitating alleviating the mold printing problem that may be caused by the removal of the buffer layer 22 in the edge region A2.

In some embodiments, a substrate of the second double-sided adhesive pad 63 is the same as a material of the buffer layer 22. In this way, in the process of attaching the heat dissipation film 62, the difference in attachment pressure experienced by the display panel 61 in the main body region A1 and the edge region A2 may be further reduced, facilitating alleviating the mold printing problem that may be caused by the removal of the buffer layer 22 in the edge region A2.

In some embodiments, the substrate of the second double-sided adhesive pad 63 includes foam. In this way, the second double-sided adhesive pad 63 plays a role in buffering in the process of attaching the heat dissipation film 62, which may ameliorate the mold printing problem that may be caused by the removal of the buffer layer 22 in the edge region A2.

In particular implementations, the substrate of the second double-sided adhesive pad 63 may also include polyethylene terephthalate, which is not limited in the present disclosure.

In order to satisfy the adhesion requirement of the second double-sided adhesive pad 63, the thickness of the second double-sided adhesive pad 63 may be, for example, greater than or equal to 0.03 mm.

In some embodiments, as shown in FIG. 6 or FIG. 7, the display module further includes: a first support film 64 disposed between the display region B1 and the heat dissipation film 62. An end surface S1 of the first support film 64 facing the bending region B2 is a plane perpendicular to the display region B1.

In the related art, the bending region B2 may be overstretched to further narrow the frame. As shown in FIG. 6, after the bending region B2 is overstretched, a shape of a longitudinal cross-section of the bending region B2 changes from a semi-circular shape to a semi-elliptical shape, so that a bending arc height A may be reduced is realized, thereby the frame is narrowed. For example, in FIG. 6, the overstretch size for the bending region B2 is 0.05 mm, and the bending arc height A is correspondingly reduced by 0.05 mm. The inventor has found that, when the end surface S1 of the first support film 64 facing the bending region B2 is the plane perpendicular to the display region B1, the stress at a junction position between the display region B1 and the bending region B2 in an overstretched state is greatly increased, which may easily lead to problems such as cracking of the display panel 61 or line breakage.

In order to ameliorate the above-mentioned problems, in some embodiments, as shown in FIGS. 7 and 8, the end surface S1 of the first support film 64 facing the bending region B2 includes a first side edge 81 close to the display region B1 and a second side edge 82 away from the display region B1. An orthographic projection of the first side edge 81 on a plane where the display region B1 is located is located at a side of an orthographic projection of the second side edge 82 on the plane where the display region B1 is located away from the bending region B2.

In the present embodiment, the end surface S1 of the first support film 64 facing the bending region B2 is an inclined surface intersecting the plane where the display region B1 is located, and the first side edge 81 is inclined towards a side close to an effective display region AA, in this way, an initial bending position of the bending region B2 may move towards the side of the effective display region AA, thereby the shape of the bending region B2 is improved and the problem of stress concentration at the junction position of the display region B1 and the bending region B2 in the overstretched state is alleviated or avoided.

Exemplarily, the inclined end surface S1 of the first support film 64 may be realized by using a laser cutting method.

In some embodiments, as shown in FIG. 8, a distance B between the orthographic projection of the first side edge 81 on the plane where the display region B1 is located and the orthographic projection of the second side edge 82 on the plane where the display region B1 is located is greater than or equal to 0.02 mm and less than or equal to 0.05 mm. Since a distance that the initial bending position of the bending region B2 moves towards the side of the effective display region AA is equal to the distance B between the orthographic projection of the first side edge 81 on the plane where the display region B1 is located and the orthographic projection of the second side edge 82 on the plane where the display region B1 is located, the distance that the initial bending position of the bending region B2 moves towards the side of the effective display region AA is greater than or equal to 0.02 mm and less than or equal to 0.05 mm.

As shown in FIG. 8, the first support film 64 includes a base film 83, and a bottom film 84 and a release film 85 located at two sides of the base film 83. A side of the base film 83 close to the bottom film 84 is provided with an adhesive for adhering and fixing the base film 83 to the display region B1 after the bottom film 84 is torn off. The release film 85 may be torn off when the base film 83 is attached to the heat dissipation film 62.

In some embodiments, as shown in FIG. 6 or FIG. 7, the display module further includes: a second support film 65 disposed between the binding region B3 and the heat dissipation film 62. An end surface S2 of the second support film 65 facing the bending region B2 is retracted away from the bending region B2 with respect to the end surface S1 of the first support film 64 facing the bending region B2.

Exemplarily, as shown in FIG. 6 or FIG. 7, the end surface S2 of the second support film 65 facing the bending region B2 may be perpendicular to the plane where the display region B1 is located.

In some embodiments, the shape of the longitudinal cross-section of the bending region B2 is semi-circular (as shown in FIG. 7) or semi-elliptical (as shown in FIG. 6), and the longitudinal cross-section is perpendicular to the plane where the display region B1 is located and perpendicular to a boundary line between the display region B1 and the bend region B2, i.e., the cross-sections shown in FIGS. 6 and 7.

Exemplarily, the bending region B2 may be in a non-overstretched state, and the shape of the longitudinal cross-section of the bending region B2 is semi-circular, as shown in FIG. 7. For example, the bending arc height A of the bending region B2, i.e., a bending radius or a radius of the circle, may be 0.3 mm, 0.25 mm, 0.2 mm, 0.17 mm or 0.15 mm.

When the bending radius R is 0.15 mm and the thicknesses of the first support film 64 and the second support film 65 are 0.088 mm, it is calculated that the total thickness of the composite film layer 20 in the edge region A2 and the second double-sided adhesive pad 63 is 0.124 mm. If the thickness of the metal layer 23 is 0.03 mm, the thickness of the second double-sided adhesive pad 63 is 0.094 mm, which satisfies the adhesion requirement.

Exemplarily, the bending region B2 may be in the overstretched state, and the shape of the longitudinal cross-section of the bending region B2 is semi-elliptical, as shown in FIG. 6. The bending arc height A of the bending region B2, i.e., a short radius of the ellipse, is less than a long radius of the ellipse. For example, the long radius of the ellipse may be 0.3 mm, 0.25 mm, 0.2 mm, 0.17 mm or 0.15 mm.

Exemplarily, the display panel 61 may include a light-emitting device. For example, the light-emitting device may be an organic light-emitting diode (OLED), a quantum dot light-emitting diode (QLED), a mini light-emitting diode (Mini LED), or a micro light-emitting diode (Micro LED).

A display apparatus is provided by the present disclosure, which includes: a display module according to any one of the embodiments, as shown in FIG. 6 or FIG. 7; and a drive assembly connected to the binding region B3 of the display panel 61 and configured to drive the display panel 61 to display a picture.

It may be appreciated by a person skilled in the art that the display apparatus provided by the present disclosure has the advantages of the above-mentioned display module.

The display apparatus provided by the present disclosure may be any product or component with a display function, such as a mobile phone, a tablet computer, a television, a displayer, a notebook computer, a digital photo frame, a vehicle-mounted display device, a smart watch, a fitness wrist strap, and a personal digital assistant.

In the present disclosure, the meaning of “plurality of” is “two or more”, and the meaning of “at least one” is “one or more”, unless explicitly and particularly defined otherwise.

In the present disclosure, the terms that indicate orientation or position relations, such as “upper” and “lower”, are based on the orientation or position relations shown in the drawings, and are merely for conveniently describing the present disclosure and simplifying the description, rather than indicating or implying that the device or element must have the specific orientation and be constructed and operated according to the specific orientation. Therefore, they should not be construed as a limitation on the present disclosure.

In the present text, the terms “include”, “contain” or any variants thereof are intended to cover non-exclusive inclusions, so that processes, methods, articles or devices that include a series of elements do not only include those elements, but also include other elements that are not explicitly listed, or include the elements that are inherent to such processes, methods, articles or devices. Unless further limitation is set forth, an element defined by the wording “including a . . . ” does not exclude additional same element in the process, method, article or device including the element.

The “one embodiment”, “some embodiments”, “exemplary embodiments”, “one or more embodiments”, “example”, “one example” or “some examples” as used herein are intended to indicate that specific features, structures, materials or characteristics related to the embodiment or example are included in at least one embodiment or example of the present disclosure. The illustrative indication of the above terms does not necessarily refer to the same one embodiment or example. Moreover, the specific features, structures, materials or characteristics may be included in any one or more embodiments or examples in any suitable manner.

In the present text, relation terms such as first and second are merely intended to distinguish one entity or operation from another entity or operation, and that does not necessarily require or imply that those entities or operations have therebetween any such actual relation or order.

In the description on some embodiments, “couple” and “connect” may be used. For example, in the description on some embodiments, the term “connect” may be used to indicate that two or more components directly physically contact or electrically contact each other. As another example, in the description on some embodiments, the term “couple” may be used to indicate that two or more components directly physically contact or electrically contact each other. However, the term “couple” or “communicatively couple” may also indicate that two or more components do not directly contact each other, but still cooperate with each other or act on each other. The embodiments disclosed herein are not necessarily limited by the contents herein.

“At least one of A, B and C” and “at least one of A, B or C” have the same meaning, and both of them include the following combinations of A, B and C: solely A, solely B, solely C, the combination of A and B, the combination of A and C, the combination of B and C, and the combination of A, B and C.

“A and/or B” include the following three combinations: solely A, solely B, and the combination of A and B.

As used herein, with reference to the context, the term “if” is optionally interpreted as meaning “when” or “in response to determining that” or “in response to detecting that”. Similarly, with reference to the context, the phrase “if it has been determined that” or “if the stated condition or event has been detected” is optionally interpreted as referring to “when it has been determined that” or “in response to determining . . . ” or “when the stated condition or event has been detected” or “in response to the stated condition or event having been detected”.

The “for” or “configured for” as used herein is intended as opened and inclusive languages, and does not exclude apparatuses adapted for or configured for executing additional tasks or steps.

The “based on” or “according to” as used herein means opening and inclusive. The processes, steps, calculations or other actions based on one or more conditions or values may be based on other conditions or exceed the values in practice. The processes, steps, calculations or other actions according to one or more conditions or values may be according to other conditions or exceed the values in practice.

As used herein, “about”, “substantially” or “approximately” includes the described value and the average value within an acceptable deviation range of the particular value, wherein the acceptable deviation range is decided by the discussed measurement that a person skilled in the art has taken into consideration and the error relevant to the measurement on the specific quantity (i.e., the limitation of the measuring system).

As used herein, “parallel”, “perpendicular”, “equal” and “flushing” include the described case and cases similar to the described case, wherein the range of the similar cases is within an acceptable deviation range, wherein the acceptable deviation range is decided by the discussed measurement that a person skilled in the art has taken into consideration and the error relevant to the measurement on the specific quantity (i.e., the limitation of the measuring system). For example, “parallel” includes absolute parallelism and approximate parallelism, wherein the acceptable deviation range of the approximate parallelism may, for example, be deviations within 5°. “Perpendicular” includes absolute perpendicularity and approximate perpendicularity, wherein the acceptable deviation range of the approximate perpendicularity may also, for example, be deviations within 5°. “Equal” includes absolute equality and approximate equality, wherein the acceptable deviation range of the approximate equality may, for example, be that the difference between the two equal instances is less than or equal to 5% of any one of them. “Flushing” includes absolute flushing and approximate flushing, wherein the acceptable deviation range of the approximate flushing may, for example, be that the distance between the two flushing instances is less than or equal to 5% of the dimension of any one of them.

It should be understood that, when a layer or element is described as on another layer or a base board, the layer or element may be directly on another layer or the base board, or an intermediate layer may also exist between the layer or element and the another layer or the base board.

The exemplary embodiments are described herein with reference to sectional views and/or plan views as idealized illustrative figures. In the drawings, in order for clarity, the thicknesses of the layers and the regions are exaggerated. Therefore, alterations from the shapes of the figures as the result of, for example, fabricating techniques and/or tolerances can be envisaged. Therefore, the exemplary embodiments should not be interpreted as limited to the shapes of the regions shown herein, but should include the shape deviations caused by, for example, fabrication. For example, an etching region illustrated as rectangular generally has a curved feature. Therefore, the regions shown in the drawings are essentially illustrative, and their shapes are not intended to illustrate the practical shapes of the regions of the device, and are not intended to limit the scopes of the exemplary embodiments.

Finally, it should be noted that the above embodiments are merely intended to explain the technical solutions of the present disclosure, and not to limit them. Although the present disclosure is explained in detail with reference to the above embodiments, a person skilled in the art should understand that he can still modify the technical solutions set forth by the above embodiments, or make equivalent substitutions to part of the technical features of them. However, those modifications or substitutions do not make the essence of the corresponding technical solutions depart from the spirit and scope of the technical solutions of the embodiments of the present disclosure.

1. A heat dissipation film, comprising a main body region and an edge region located at one side of the main body region, the heat dissipation film comprising a composite film layer; the composite film layer in the main body region comprising an adhesive layer, a buffer layer and a first metal portion of a metal layer that are arranged in layer configuration, and the composite film layer in the edge region comprising a second metal portion of the metal layer, wherein a thickness of the composite film layer in the edge region is less than a thickness of the composite film layer in the main body region;
the adhesive layer and the buffer layer do not overlap with the edge region in a normal direction of the heat dissipation film;
the metal layer further comprises
a connecting portion configured to connect the first metal portion and the second metal portion;
wherein the first metal portion, the second metal portion and the connecting portion jointly cover the main body region and the edge region in the normal direction of the heat dissipation film.

2. The heat dissipation film according to claim 1, wherein the metal layer comprises a first surface; a first surface of the first metal portion is in contact with the buffer layer, and a first surface of the second metal portion is located in a same plane as a surface of a side of the adhesive layer facing away from the first metal portion.

3. The heat dissipation film according to claim 2, wherein the metal layer further comprises a second surface disposed opposite to the first surface; the heat dissipation film further comprises:
a support structure located in the edge region and disposed on a second surface of the second metal portion; and
a surface of a side of the support structure facing away from the second metal portion is located in a same plane as a second surface of the first metal portion.

4. The heat dissipation film according to claim 3, wherein the heat dissipation film further comprises:
a first release protective film located in the edge region and disposed at the side of the support structure facing away from the second metal portion;
wherein the support structure comprises a support pad, a single surface of the support pad is provided with an adhesive, and the adhesive-provided surface faces the first release protective film.

5. The heat dissipation film according to claim 3, wherein the heat dissipation film further comprises:
a second release protective film located in the main body region and disposed on the second surface of the first metal portion.

6. The heat dissipation film according to claim 3, wherein the support structure comprises:
a first double-sided adhesive pad adhered to and fixed on the second surface of the second metal portion; and
a removable pad disposed at a side of the first double-sided adhesive pad facing away from the second metal portion, wherein the removable pad is removable from the side of the first double-sided adhesive pad facing away from the second metal portion.

7. The heat dissipation film according to claim 1, wherein the heat dissipation film further comprises:
a bottom protective film disposed at a side of the adhesive layer facing away from the metal layer;
wherein the bottom protective film is capable of being torn off in a process of attaching the heat dissipation film to a display panel.

8. The heat dissipation film according to claim 1, wherein the adhesive layer is a grid-like adhesive layer to remove air bubbles in a process of attaching the heat dissipation film.

9. The heat dissipation film according to claim 1, wherein the metal layer is a copper foil layer.

10. A display module, comprising:
a display panel, comprising a display region, a bending region and a binding region, wherein the binding region is bent to a side of the display region facing away from a light-emitting side through the bending region; and
the heat dissipation film according to claim 1, wherein the heat dissipation film is located between the display region and the binding region, the adhesive layer is disposed close to the display region, and an orthographic projection of the binding region on the heat dissipation film overlaps with the edge region.

11. The display module according to claim 10, wherein the display module further comprises:
a second double-sided adhesive pad disposed between a composite film layer in the edge region and the binding region and configured to adhere and fix the binding region at a side of the composite film layer in the edge region facing away from the display region.

12. The display module according to claim 11, wherein in a state where a compression ratio is 25%, a compression force deflection value of the second double-sided adhesive pad and a compression force deflection value of the buffer layer are greater than or equal to 0.02 MPa and less than or equal to 0.4 MPa.

13. The display module according to claim 11, wherein a substrate of the second double-sided adhesive pad is the same as a material of the buffer layer.

14. The display module according to claim 11, wherein a substrate of the second double-sided adhesive pad and a material of the buffer layer comprise foam.

15. The display module according to claim 11, wherein a thickness of the second double-sided adhesive pad is greater than or equal to 0.03 mm.

16. The display module according to claim 10, wherein the display module further comprises:
a first support film disposed between the display region and the heat dissipation film, wherein an end surface of the first support film facing the bending region comprises a first side edge close to the display region and a second side edge away from the display region; an orthographic projection of the first side edge on a plane where the display region is located is located at a side of an orthographic projection of the second side edge on the plane where the display region is located away from the bending region.

17. The display module according to claim 16, wherein a distance between the orthographic projection of the first side edge on the plane where the display region is located and the orthographic projection of the second side edge on the plane where the display region is located is greater than or equal to 0.02 mm and less than or equal to 0.05 mm.

18. The display module according to claim 16, wherein the first support film comprises a base film, and a bottom film and a release film located at two sides of the base film;
a side of the base film close to the bottom film is provided with an adhesive for adhering and fixing the base film to the display region after the bottom film is torn off; and
the release film is capable of being torn off when the base film is attached to the heat dissipation film.

19. The display module according to claim 10, wherein a shape of a longitudinal cross-section of the bending region is semi-circular or semi-elliptical, and the longitudinal cross-section is perpendicular to the plane where the display region is located and perpendicular to a boundary line between the display region and the bending region.

20. A display apparatus, comprising:
the display module according to claim 10; and
a drive assembly connected to a binding region of the display panel and configured to drive the display panel to display a picture.
